(19) United States
(12) Patent Application Publication
(10) Pub. No.: US 2002/0079489 A1
(43) Pub. Date: Jun. 27, 2002

(54) Organic electroluminescent device

(76) Inventors: Hitoshi Ishikawa, Tokyo (JP); Satoru Toguchi, Tokyo (JP); Hiroshi Tada, Tokyo (JP); Atsushi Oda, Tokyo (JP)

Correspondence Address: McGinn & Gibb, PLLC, Suite 200, 8321 Old Courthouse Road, Vienna, VA, 22182-3817, US

(21) Appl. No.: 10/023,741

(22) Filed: Dec. 21, 2001

(30) Foreign Application Priority Data
Dec. 25, 2000 (JP) 2000-392906

(51) Int. Cl. H01L 35/24

(52) U.S. Cl. 257/40; 257/79; 257/94; 257/103

(57) ABSTRACT

An organic electroluminescent (EL) device including an anode, a cathode, and an emitting layer and at least one organic thin-film layer which are sandwiched between said anode and said cathode, said organic thin-film layer including compound expressed by the following general formula [I], [II] or [III]. The organic EL device suppresses the light emission from the emitting layer, thereby generating original blue light emission. The above compound exhibits an excellent electron-transporting property, and the emitting layer containing the compound improves the device performance.

B:X(A)ₙ [I]

A₁—A₂ [II]

B₁—B₂ [III]

### BACKGROUND OF THE INVENTION

(a) Field of the Invention

The present invention relates to an organic electroluminescent device (hereinafter referred to as “organic EL device) having an excellent luminescent property.

(b) Description of the Related Art

An organic EL device is a light-emitting device which makes use of the principle that when an electric field is applied, a fluorescent material emits light in response to the charge recombination of holes injected from an anode and electrons injected from a cathode.

After C. W. Tang et al. of Eastman Kodak Company reported a low-voltage-driven organic EL device using a double layered structure (C. W. Tang, S. A. Vanslyke, Applied Physics Letters, Vol. 51, 913 (1987)), studies on an organic EL device using an organic material have been briskly carried out.

Tang et al. reported an organic EL device using tris(8-quinolinol aluminum) in an emitting layer and a triphenyldiamine derivative in a hole-transporting layer. This stacked structure gives such advantages as an improvement in the injection efficiency of holes into the emitting layer; blocking of electrons injected from the cathode, which increases the efficiency of exciton production from charge recombination; and confinement of the excitons into the emitting layer. A double layered structure composed of a hole-injecting and transporting layer and an electron-transporting and emitting layer or a triple layered structure composed of a hole-injecting and transporting layer, an emitting layer and an electron-injecting and transporting layer is well known as an organic EL device. In order to increase the recombination efficiency of injected holes and electrons, various improvements in the device structure or fabrication process have been introduced to such multi-layered devices.

As a hole transporting material, triphenylamine derivatives and aromatic diamine derivatives such as 4,4′,4″-tris(3-methylphenylphenylamino)-triphenylamine and N,N′-diphenyl-N,N′-bis(3-methylphenyl)-[1,1′-biphenyl]-4,4′-diamine which are star burst type compounds are well known (for example, JP-A-8(1996)-20771, JP-A-8(1996)-40995, JP-A-8(1996)-40997, JP-A-8(1996)-53397, and JP-A-8(1996)-87122).

As an electron transporting material, oxadiazole derivatives, triazole derivatives and the like are well known. Chelate complexes such as tris(8-quinolinolate)aluminum complex, coumarin derivatives, tetraphenylbutadiene derivatives, bisstyrylarylene derivatives, oxadiazole derivatives and the like are known as emitting materials. Since various color light in a visible region from blue to red are obtained from these emitting materials, there is increased expectation for industrialization of a full color organic EL device (refer to, e.g., JP-A-8(1996)-239655, JP-A-7(1995)-138561, and JP-A-3(1991)-200889).

The various organic EL devices with high brightness and high efficiency have been reported. However, in these organic EL devices, light emission is observed in the electron-transporting layer in addition to the emitting layer. Although materials for emitting pure blue used in a color display device especially in a blue color emitting device have been reported, the EL light emission from the emitting material is likely to be overlapped with the light emission from the electron-transporting layer in the organic EL device using the materials, resulting in the failure of the emission of pure blue light.

The improvement of the injection property of electrons is required for improving the performance of the device, and a material having an excellent injection property is demanded.

### SUMMARY OF THE INVENTION

It is therefore an object of the present invention to provide an organic EL device emitting blue light having an excellent color purity with higher efficiency.

It is another object of the present invention to provide an organic EL device using a material having an excellent electron injection property.

Thus, the present invention provides an organic electroluminescent (EL) device including an anode, a cathode, and an emitting layer and at least one organic thin-film layer which are sandwiched between said anode and said cathode, said organic thin-film layer including compound expressed by the following general formula [I], [II] or [III]:

B:X(A)ₙ [I]

A₁—A₂ [II]

B₁—B₂ [III]

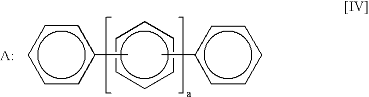

(wherein “X” in the general formula [I] designates a connecting organic group having an “n” valency (“n” is an integer between 2 and 4 both inclusive) excluding condensed polycyclic hydrocarbon compounds; “A” independently designates “n” number of substituted or non-substituted polyphenylene groups in a general formula [IV] (“a” is an integer between 0 and 18 both inclusive); when “X” is benzene group, “A” independently designates the substituted or non-substituted polyphenylene groups in the general formula [IV] (“a” is the integer between 0 and 18 both inclusive) in which “n” is 3 or 4; when “X” is vinylene group, “A” independently designates the substituted or non-substituted polyphenylene groups in the general formula [IV] (“a” is the integer between 0 and 18 both inclusive) in which “n” is 2; A₁ and A₂ in the general formula [II] independently designate substituted or non-substituted polyphenylene groups in the general formula [IV]; and B₁ and B₂ in the general formula [III] independently designate the group represented by the general formula [I]).

In accordance with the present invention, the organic EL device including the compound represented by the general formula [I], [II] or [III] especially between the emitting layer and the electron-transporting layer suppresses the light emission from the emitting layer, thereby generating original blue light emission. Further, the above compound itself or the above compound doped with a metal exhibits an excellent electron-transporting property, and the emitting layer containing the compound improves the device performance.

The above and other objects, features and advantages of the present invention will be more apparent from the following description.

### BRIEF DESCRIPTION OF DRAWINGS

FIG. 1 is a schematic sectional view showing an organic EL device illustrating an embodiment of the present invention.

FIG. 2 is a schematic sectional view showing an organic EL device illustrating another embodiment.

FIG. 3 is a schematic sectional view showing an organic EL device illustrating a further embodiment.

FIG. 4 is a schematic sectional view showing an organic EL device illustrating a still further embodiment.

FIG. 5 is a schematic sectional view showing an organic EL device illustrating a still further embodiment.

FIG. 6 is a schematic sectional view showing an organic EL device illustrating a still further embodiment.

### PREFERRED EMBODIMENTS OF THE INVENTION

Now, the present invention is more specifically described.

The intensive investigation by the present inventors has revealed that the insertion of a middle layer including a specified compound having a polyphenylene unit especially between an emitting layer and a cathode in an organic EL device including the emitting layer and an electron-transporting layer suppresses the light-emission from the electron-transporting layer. The above insertion enables a single-layered device having no electron-transporting layer, thereby generating the blue light emission only from the emitting layer.

Further, the present inventors have revealed that a layer including a specified compound having arylene polyphenylene units and doped with a metal has an electron-transporting property, and the device performance is improved by mixing the specified compound with the emitting layer or the electron-transporting layer.

In the present invention, bonding of a plurality of the polyphenylene contained in the middle layer between the emitting layer and the electron-transporting layer (not linearly) suppresses the crystallization which is likely to take place in the linear form. The crystallization also can be suppressed by inserting a connecting organic group other than a condensed organic group, and a branched structure into a linear structure.

A group “A” represented by a general formula [IV] is substituted or non-substituted polyphenylene group. A substituent group which may exist in the polyphenylene group includes halogen atom, hydroxyl group, nitro group, carbonyl group, substituted or non-substituted alkyl group, substituted or non-substituted alkenyl group, substituted or non-substituted cycloalkyl group, substituted or non-substituted alkoxy group, substituted or non-substituted aryloxy group, substituted or non-substituted alkoxycarbonyl group substituted or non-substituted amino group.

Examples of the substituted or non-substituted alkyl group include methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinirtroisopropyl group, 2,3-dinitro-t-butyl group, 1,2,3-trinitropropyl group.

Examples of the substituted or non-substituted alkenyl group include vinyl group, allyl group, 1-butenyl group, 2-butenyl group, 3-butenyl group, 1,3-butanedienyl group, 1-methylvinyl group, styryl group, 2,2-diphenylvinyl group, 1,2-diphenylvinyl group, 1-methylallyl group, 1,1-dimethylallyl group, 2-methylallyl group, 1-phenylallyl group, 2-phenylallyl group, 3-phenylallyl group, 3,3-diphenylallyl group, 1,2-dimethylallyl group, 1-phenyl-1-butenyl group and 3-phenyl-1-butenyl group.

Examples of the substituted or non-substituted cycloalkyl group include cyclopropyl group, cyclobutyl group, cyclopentyl group, cyclohexyl group, 4-methylcyclohexyl group.

Examples of the substituted or non-substituted alkoxy group include groups represented by —OY wherein Y may be methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-chloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodo isopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group and 1,2,3-trinitropropyl group.

The substituted or non-substituted aryloxy group is represented by —OZ, wherein Z may be phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-pyrrolyl group, 3-pyrrolyl group, pyrazinyl group, 2-pyridinyl group, 3-pyridinyl group, 4-pyridinyl group, 2-indolyl group, 3-indolyl group, 4-indolyl group, 5-indolyl group, 6-indolyl group, 7-indolyl group, 1-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthroline-2-yl group, 1,7-phenanthroline-3-yl group, 1,7-phenanthroline-4-yl group, 1,7-phenanthroline-5-yl group, 1,7-phenanthroline-6-yl group, 1,7-phenanthroline-8-yl group, 1,7-phenanthroline-9-yl group, 1,7-phenanthroline-10-yl group, 1,8-phenanthroline-2-yl group, 1,8-phenanthroline-3-yl group, 1,8-phenanthroline-4-yl group, 1,8-phenanthroline-5-yl group, 1,8-phenanthroline-6-yl group, 1,8-phenanthroline-7-yl group, 1,8-phenanthroline-9-yl group, 1,8-phenanthroline-10-yl group, 1,9-phenanthroline-2-yl group, 1,9-phenanthroline-3-yl group, 1,9-phenanthroline-4-yl group, -1,9-phenanthroline-5-yl group, 1,9-phenanthroline-6-yl group, 1,9-phenanthroline-7-yl group, 1,9-phenanthroline-8-yl group, 1,9-phenanthroline-10-yl group, 1,10-phenanthroline-2-yl group, 1,10-phenanthroline-3-yl group, 1,10-phenanthroline-4-yl group, 1,10-phenanthroline-5-yl group, 2,9-phenanthroline-1-yl group, 2,9-phenanthroline-3-yl group, 2,9-phenanthroline-4-yl group, 2,9-phenanthroline-5-yl group, 2,9-phenanthroline-6-yl group, 2,9-phenanthroline-7-yl group, 2,9-phenanthroline-8-yl group, 2,9-phenanthroline-10-yl group, 2,8-phenanthroline-1-yl group, 2,8-phenanthroline-3-yl group, 2,8-phenanthroline-4-yl group, 2,8-phenanthroline-5-yl group, 2,8-phenanthroline-6-yl group, 2,8-phenanthroline-7-yl group, 2,8-phenanthroline-9-yl group, 2,8-phenanthroline-10-yl group, 2,7-phenanthroline-1-yl group, 2,7-phenanthroline-3-yl group, 2,7-phenanthroline-4-yl group, 2,7-phenanthroline-5-yl group, 2,7-phenanthroline-6-yl group, 2,7-phenanthroline-8-yl group, 2,7-phenanthroline-9-yl group, 2,7-phenanthroline-10-yl group, 1-phenazinyl group, 2-phenazinyl group, 1-phenothiazinyl group, 2-phenothiazinyl group, 3-phenothiazinyl group, 4-phenothiazinyl group, 1-phenoxazinyl group, 2-phenoxazinyl group, 3-phenoxazinyl group, 4-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrole-1-yl group, 2-methylpyrrole-3-yl group, 2-methylpyrrole-4-yl group, 2-methylpyrrole-5-yl group, 3-methylpyrrole-1-yl group, 3-methylpyrrole-2-yl group, 3-methylpyrrole-4-yl group, 3-methylpyrrole-5-yl group, 2-t-butylpyrrole-4-yl group, 3-(2-phenylpropyl)pyrrole-1-yl group, 2-methyl-1-indolyl group, 4-methyl-1-indolyl group, 2-mehyl-3-indolyl group, 4-methyl-3-indolyl group, 2-t-butyl-1-indolyl group, 4-t-butyl-1-indolyl group, 2-t-butyl-3-indolyl group and 4-t-butyl-3-indolyl group.

The substituted or non-substituted alkoxycarbonyl group is represented by —COOY, wherein Y may be methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-clinitroisopropyl group, 2,3-dinitro-t-butyl group and 1,2,3-trinitropropyl group.

The substituted or non-substituted amino group is represented by —NX₁X₂, wherein X₁ and X₂, independently from each other, may be hydrogen atom, methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-chloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodo isopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group and 1,2,3-trinitropropyl group.

The compound of the present invention is represented by the general formula [I], [II] or [III]. Although examples of the compounds will be listed, the compounds usable in the present invention are not restricted thereto.

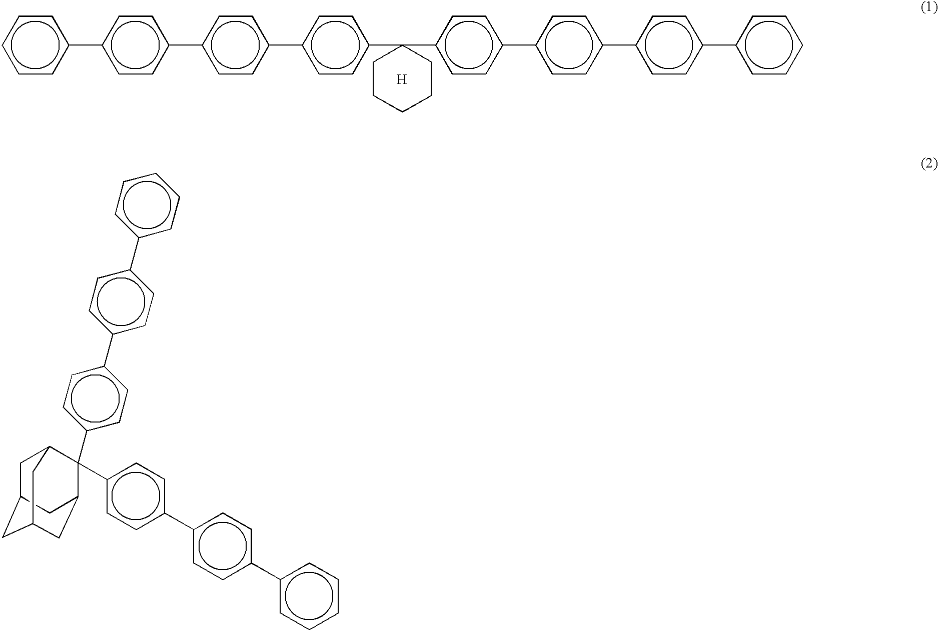

Among these compounds (1) to (6), the “X”, “n” and “a” in the general formula [I] is cyclohexylidene group, 2 and 2, respectively, in the compound (1); amamantylidene group, 2 and 1, respectively, in the compound (2); and amamantylidene group, 2 and 4, respectively, in the compound (3). In the compound (4), both of A₁ and A₂ in the general formula [II] have a=3. In the compound (5), both of B₁ and B₂ in the general formula [III] are cyclohexylidene groups, and have n=2 and a=1. In the compound (6), “X” in the general formula [I] is benzene group, and have n=3 and a=4.

The metal mixed with the compound [I], [II] or [III] of the present invention may improve the electron injection property by the mixing with the compound and includes an alkaline metal such as Li, Na, K, Rb, Cs and Fr, an alkaline earth metal such as Mg, Ca, Sr, Ba and Ra; and other metals such as Al, Ga In and Tl.

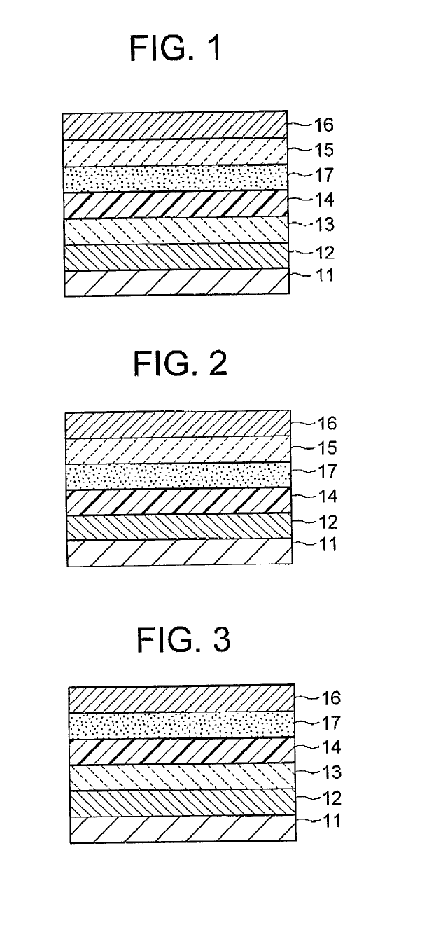

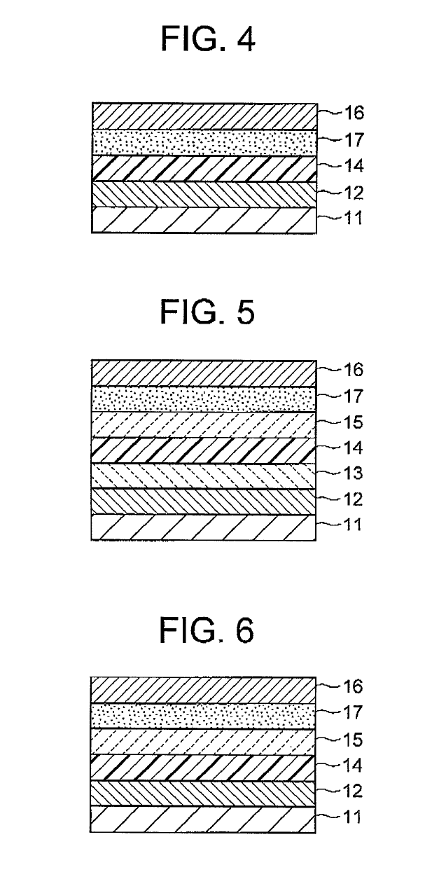

The structure of the organic EL device of the present invention includes one or more organic thin-film layers between the electrodes, and examples thereof include that having an anode 12, a hole-transporting layer 13, an emitting layer 14, a middle layer 17, an electron-transporting layer 15 and a cathode 16 stacked in this turn on a glass substrate 11 as shown in FIG. 1, that having the anode 12, the emitting layer 14, the middle layer 17, the electron-transporting layer 15 and the cathode 16 stacked in this turn on the glass substrate 11 as shown in FIG. 2, that having the anode 12, the hole-transporting layer 13, the emitting layer 14, the middle layer 17 and the cathode 16 stacked in this turn on the glass substrate 11 as shown in FIG. 3, that having the anode 12, the emitting layer 14, the middle layer 17 and the cathode 16 stacked in this turn on the glass substrate 11 as shown in FIG. 4, that having the anode 12, the hole-transporting layer 13, the emitting layer 14, the electron-transporting layer 15, the middle layer 17 and the cathode 16 stacked in this turn on the glass substrate 11 as shown in FIG. 5, and that having the anode 12, the emitting layer 14, the electron-transporting layer 15, the middle layer 17 and the cathode 16 stacked in this turn on the glass substrate 11 as shown in FIG. 6. Among these structures, the structures shown in FIGS. 2, 4 and 6 are preferable in which the emitting layer 14 is adjacent to the anode 12.

For the purposes of improving the electron injection property and the light emission efficiency and of suppressing the insulation destruction, a thin layer may be inserted which is formed by a dielectric or an insulator such as lithium fluoride, silicon oxide, silicon dioxide and silicon nitride; a mixed layer formed by an organic layer and an electrode material or a metal; and an organic polymer thin film formed by polyaniline, polyacetylene derivative, polydiacetylene derivative, polyvinylcarbazol derivative or polyparaphenylenevinylene derivative. The insertion may be between any adjacent layers except that between any two adjacent layers among the emitting layer 14, the middle layer 17 and the electron-transporting layer 15.

There are no particular limitation on the emitting material used for the emitting layer 14 in the present invention, and any compound that is usually used as an emitting material can be used. Examples of the materials include, but not limited to, a lower molecular weight emitting material such as bisdiphenylvinylphenyl (BDPVBi) [1], 1,3-bis(p-t-butylphenyl-1,3,4-oxadiazolyl)phe nyl (OXD-7) [2], N,N′-bis(2,5-di-t-butylphenyl)perylene tetracarboxylic acid diimide (BPPC) [3] and 1,4-bis(N-p-tolyl-N-4-(4-methylstyryl)phenylamino) naphthalene [4], and a higher molecular weight emitting material such as polyphenylenevinylene-based polymer.

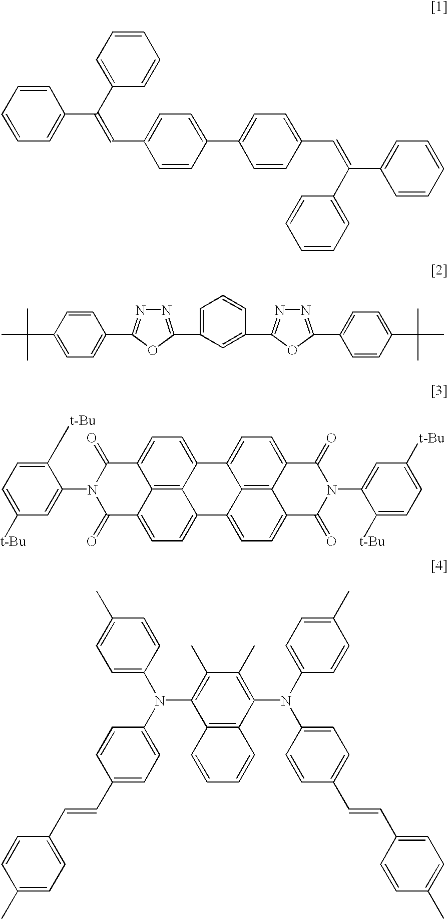

An emitting material prepared by doping the electron-transporting material with a fluorescent material may be used in the emitting layer 14. For example, doped materials may be used therefor such as a material prepared by doping quinolinol metal complex such as Alq₃ with quinacridone derivative such as 4-dicyanomethylene-2-methuyl-6-(p-dimethylamino-styryl)-4H-pyran (DCM) [5] and 2,3-quinacridone [6] or coumarin derivative such as 3-(2′-benzothiazole)-7-diethyl-aminocoumarin [7]. Another material prepared by doping the electron-transporting material such as bis (2-methyl-8-hydroxyquinoline)-4-phenylphenol-aluminum complex [8] with a condensed polycyclic aromatic compound such as perylene may be also used. A further material prepared by doping the hole-transporting material such as 4,4′-bis(m-tolylphenylamino)biphenyl (TPD) [10] with rubrene [11] may be also used.

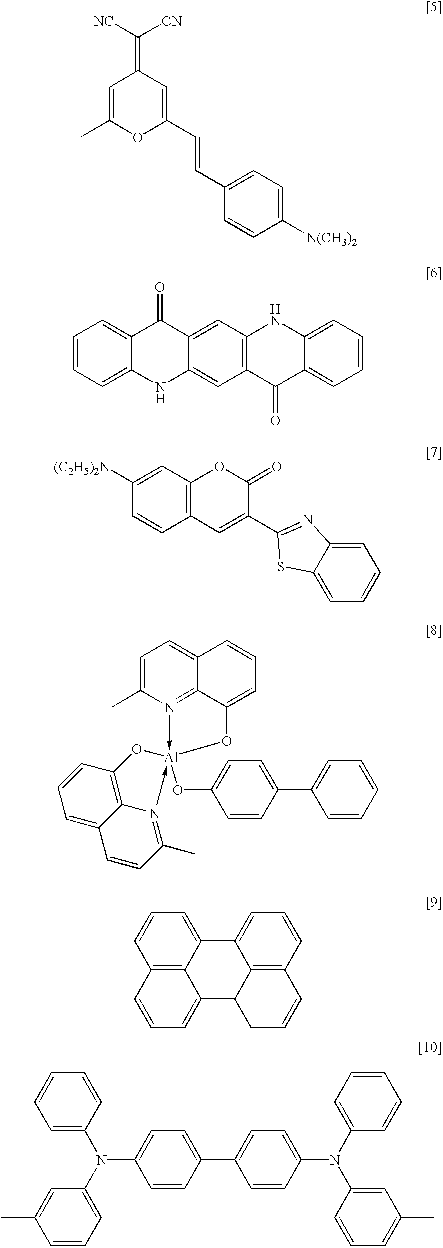

There are no particular limitation on the hole-transporting material used for the hole-transporting layer 13 in the present invention, and any compound that is usually used as a hole-transporting material can be used. Examples of the materials include, but not limited to, triphenyldiamines such as bis(di(p-tolyl)aminophenyl)-1,1-cyclohexane [12] and N,N′-diphenyl-N,N′-bis(1-naphthyl)-1,1′-biphenyl-4,4′-diamine [13]; and star burst type molecules [14] to [16].

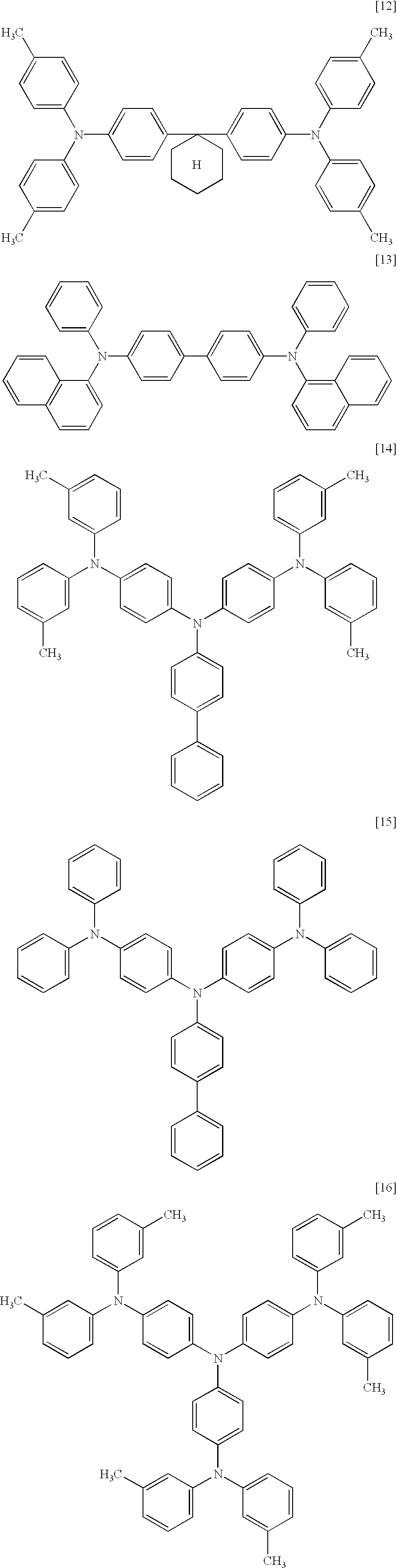

There are no particular limitation on the electron-transporting material used for the electron-transporting layer 15 in the present invention, and any compound that is usually used as an electron-transporting material can be used. Examples of the materials include, but not limited to, oxadiazole derivatives such as 2-(4-biphenylyl)-5-(4-t-butylphenyl)-1,3,4-oxadiazole (Bu-PBD) [17] and the OXD [2]; and quinolinol-based metal complex (Alq₃, [9], [20] to [23]).

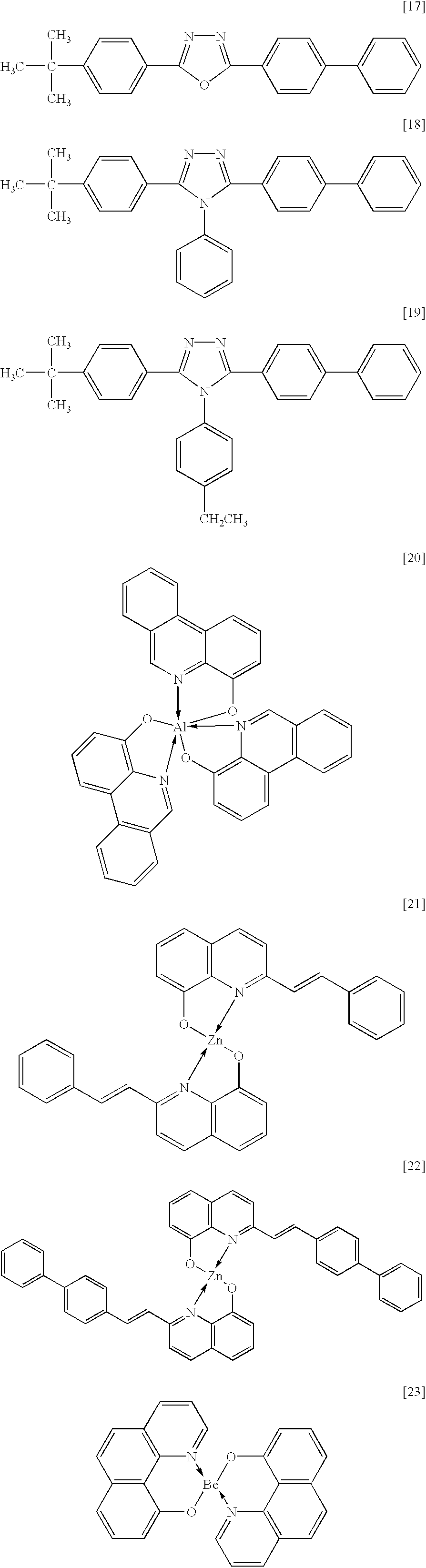

The anode 12 of the organic EL device has a role of injecting holes into the hole-transporting layer 13 and preferably has a work function of 4.5 eV or more. Examples of materials for the anode include indium tin oxide (ITO), tin oxide (NESA), gold, silver, platinum and copper.

For the purpose of injecting electrons into the electron-transporting layer 15, the metal doped layer or the emitting layer 14, the cathode 16 having a smaller work function is preferred Examples for the material for the cathode include, but not limited to, indium, aluminum, magnesium, magnesium-indium alloy, magnesium-aluminum alloy, aluminum-lithium alloy, aluminum-scandium-lithium alloy, and magnesium-silver alloy.

Processes, such as vacuum evaporation or spin-coating, generally used for fabricating a conventional EL device can be used for the organic EL device of the present invention. Examples of such processes for forming the organic thin-film layer including the compounds include, but not limited to, vacuum evaporation, molecular beam epitaxy (MBE), and dipping, spin-coating, casting, bar-coating or roll-coating of solutions wherein these compounds are dissolved into solvents.

The organic layers such as the emitting layer 14, the hole-transporting layer 13 and the electron-transporting layer 15 in the organic EL device of the present invention may have any thickness. However, a preferable thickness generally resides between several nanometers and 1 micrometer. When the film is too thin, defects such as pin holes tend to occur. When the film is too thick, on the other hand, a high-applied voltage is required, which tends to deteriorate the efficiency.

### EXAMPLE 1

An organic EL device in accordance with Example 1 of the present invention had a structure shown in FIG. 1.

An ITO film was formed on the glass substrate 11 having a dimension of 50 mm×25 mm (Hoya Corporation, NA45, 1.1 mm thick) by sputtering so that the ITO film had a sheet resistance of 20□/□ to fabricate an anode. Thereafter, the compound [13] was vacuum deposited on the anode to form a hole-transporting layer having a thickness of 50 nm. Next, the compound [4] was vacuum deposited to form an emitting layer having a film thickness of 60 nm.

Then, the compound (1) was vacuum deposited on the emitting layer, thereby forming a middle layer having a film thickness of 5 nm. Next, the compound [18] was vacuum deposited on the middle layer, thereby forming an electron-transporting layer having a film thickness of 25 nm. Thereafter, magnesium-silver alloy was vacuum deposited on the electron-transporting layer to form a cathode having a film thickness of 200 nm, thereby fabricating the organic EL device.

When a dc voltage of 7 V was applied to this organic EL device, blue light emission of 13,000 cd/m² was obtained.

### EXAMPLE 2

An organic EL device of Example 2 had a structure shown in FIG. 2.

An ITO film was formed on the glass substrate 11 having a dimension of 50 mm×25 mm (Hoya Corporation, NA45, 1.1 mm thick) by sputtering so that the ITO film had a sheet resistance of 20□/□ to fabricate an anode. Thereafter, the compound [4] was vacuum deposited on the anode to form an emitting layer having a thickness of 60 nm. Next, the compound (2) was vacuum deposited on the emitting layer to form a middle layer having a film thickness of 5 nm.

Then, the compound [18] was vacuum deposited on the middle layer, thereby forming an electron-transporting layer having a film thickness of 25 nm. Next, magnesium-silver alloy was vacuum deposited on the electron-transporting layer to form a cathode having a film thickness of 200 nm, thereby fabricating the organic EL device.

When a dc voltage of 7 V was applied to this organic EL device, blue light emission of 11,000 cd/m² was obtained.

### EXAMPLE 3

An organic EL device of Example 3 had a structure shown in FIG. 3.

An ITO film was formed on the glass substrate 11 having a dimension of 50 mm×25 mm (Hoya Corporation, NA45, 1.1 mm thick) by sputtering so that the ITO film had a sheet resistance of 20□/□ to fabricate an anode. Thereafter, the compound [13] was vacuum deposited on the anode to form a hole-transporting layer having a thickness of 50 nm. Next, the compound [4] was vacuum deposited to form an emitting layer having a film thickness of 60 nm.

Then, the compound (4) was vacuum deposited on the emitting layer to form a middle layer having a film thickness of 5 nm. Next, magnesium-silver alloy was vacuum deposited on the middle layer to form a cathode having a film thickness of 200 nm, thereby fabricating the organic EL device.

When a dc voltage of 7 V was applied to this organic EL device, blue light emission of 9,000 cd/m² was obtained.

### EXAMPLE 4

The organic EL device was fabricated in accordance with the procedures of Example 3 except that the compound (4) and Cs (using Cs dispenser available from Saes Getters Corporation) were co-deposited to form a metal-doped layer having a film thickness of 15 nm acting as the middle layer.

When a dc voltage of 7 V was applied to this organic EL device, blue light emission of 8,000 cd/m² was obtained.

### EXAMPLE 5

An organic EL device of Example 5 had a structure shown in FIG. 4.

An ITO film was formed on the glass substrate 11 having a dimension of 50 mm×25 mm (Hoya Corporation, NA45, 1.1 mm thick) by sputtering so that the ITO film had a sheet resistance of 20□/□ to fabricate an anode. Thereafter, the compound [4] was vacuum deposited on the anode to form an emitting layer having a thickness of 60 nm. Next, the compound (1) was vacuum deposited to form a middle layer having a film thickness of 5 nm.

Next, magnesium-silver alloy was vacuum deposited on the middle layer to form a cathode having a film thickness of 200 nm, thereby fabricating the organic EL device.

When a dc voltage of 7 V was applied to this organic EL device, blue light emission of 7,000 cd/m² was obtained.

### EXAMPLE 6

The organic EL device was fabricated in accordance with the procedures of Example 5 except that the compound (1) and Cs (using Cs dispenser available from Saes Getters Corporation) were co-deposited to form a metal-doped layer having a film thickness of 15 nm acting as the middle layer.

When a dc voltage of 7 V was applied to this organic EL device, blue light emission of 8,000 cd/m² was obtained.

### EXAMPLE 7

An organic EL device of Example 7 had a structure shown in FIG. 5.

An ITO film was formed on the glass substrate 11 having a dimension of 50 mm×25 mm (Hoya Corporation, NA45, 1.1 mm thick) by sputtering so that the ITO film had a sheet resistance of 20□/□ to fabricate an anode. Thereafter, the compound [13] was vacuum deposited on the anode to form a hole-transporting layer having a thickness of 50 nm. Next, the compound [4] was vacuum deposited to form an emitting layer having a thickness of 60 nm. Next, the compound [18] was vacuum deposited on the emitting layer to form an electron-transporting layer having a thickness of 25 nm.

Then, the compound (2) was vacuum deposited on the electron-transporting layer to form a middle layer having a thickness of 5 nm. Next, magnesium-silver alloy was vacuum deposited on the middle layer to form a cathode having a film thickness of 200 nm, thereby fabricating the organic EL device.

When a dc voltage of 7 V was applied to this organic EL device, blue light emission of 9,000 cd/m² was obtained.

### EXAMPLE 8

The organic EL device was fabricated in accordance with the procedures of Example 7 except that the compound (2) and Cs (using Cs dispenser available from Saes Getters Corporation) were co-deposited to form a metal-doped layer having a film thickness of 15 nm acting as the middle layer.

When a dc voltage of 7 V was applied to this organic EL device, blue light emission of 8,000 cd/m² was obtained.

### EXAMPLE 9

An organic EL device of Example 9 had a structure shown in FIG. 6.

An ITO film was formed on the glass substrate 11 having a dimension of 50 mm×25 mm (Hoya Corporation, NA45, 1.1 mm thick) by sputtering so that the ITO film had a sheet resistance of 20□/□ to fabricate an anode. Thereafter, the compound [4] was vacuum deposited on the anode to form an emitting layer having a thickness of 60 nm. Next, the compound [18] was vacuum deposited on the emitting layer to form an electron-transporting layer having a film thickness of 25 nm.

Then, the compound (1) was vacuum deposited on the electron-transporting layer, thereby forming a middle layer having a film thickness of 5 nm. Thereafter, magnesium-silver alloy was vacuum deposited on the middle layer to form a cathode having a film thickness of 200 nm, thereby fabricating the organic EL device.

When a dc voltage of 7 V was applied to this organic EL device, blue light emission of 12,000 cd/m² was obtained.

### EXAMPLE 10

The organic EL device was fabricated in accordance with the procedures of Example 9 except that the compound (1) and Cs (using Cs dispenser available from Saes Getters Corporation) were co-deposited to form a metal-doped layer having a film thickness of 15 nm acting as the middle layer.

When a dc voltage of 7 V was applied to this organic EL device, blue light emission of 10,000 cd/m² was obtained.

### COMPARATIVE EXAMPLE 1

The organic EL device was fabricated in accordance with the procedures of Example 2 except that after the formation of the emitting layer, the electron-transporting layer was formed without forming the middle layer.

When a dc voltage of 7 V was applied to this organic EL device, blue light emission of 8,000 cd/m² was obtained.

### COMPARATIVE EXAMPLE 2

The organic EL device was fabricated in accordance with the procedures of Example 4 except that after the formation of the emitting layer, the compound [18] was vacuum deposited to form the electron-transporting layer having a film thickness of 25 nm without forming the metal-doped layer.

When a dc voltage of 7 V was applied to this organic EL device, blue light emission of 6,000 cd/m² was obtained.

Since the above embodiments are described only for examples, the present invention is not limited to the above embodiments and various modifications or alterations can be easily made therefrom by those skilled in the art without departing from the scope of the present invention.

What is claimed is:

1. An organic electroluminescent (EL) device comprising an anode, a cathode, and an emitting layer and at least one organic thin-film layer which are sandwiched between said anode and said cathode, said organic thin-film layer including compound expressed by the following general formula [I], [II] or [III]:
B:X(A)ₙ [I]
A₁—A₂ [II]
B₁—B₂ [III] 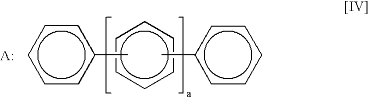
(wherein “X” in the general formula [I] designates a connecting organic group having an “n” valency (“n” is an integer between 2 and 4 both inclusive) excluding condensed polycyclic hydrocarbon compounds; “A” independently designates “n” number of substituted or non-substituted polyphenylene groups in a general formula [IV] (“a” is an integer between 0 and 18 both inclusive); when “X” is benzene group, “A” independently designates the substituted or non-substituted polyphenylene groups in the general formula [IV] (“a” is the integer between 0 and 18 both inclusive) in which “n” is 3 or 4; when “X” is vinylene group, “A” independently designates the substituted or non-substituted polyphenylene groups in the general formula [IV] (“a” is the integer between 0 and 18 both inclusive) in which “n” is 2; A₁ and A₂ in the general formula [II] independently designate substituted or non-substituted polyphenylene groups in the general formula [IV]; and B₁ and B₂ in the general formula [III] independently designate the group represented by the general formula [I]).

2. The organic EL device as defined in claim 1, wherein the compound is mixed with a metal.

3. The organic EL device as defined in claim 2, wherein an interface between the emitting layer and the cathode includes the compound mixed with the metal.

4. The organic EL device as defined in claim 2, wherein said at least one organic thin-film layer includes an electron-transporting layer, and an interface between the electron-transporting layer and the cathode includes the compound.

5. The organic EL device as defined in claim 1, wherein an interface between the emitting layer and the cathode includes the compound.

6. The organic EL device as defined in claim 1, wherein the organic thin-film layer includes an electron-transporting layer, and an interface between the emitting layer and the electron-transporting layer includes the compound.

7. An organic EL device comprising an anode, a cathode and an emitting zone sandwiched between the anode and the cathode, the emitting zone including at least one organic thin-film layer, the emitting layer including adjacent to the anode a compound expressed by the following general formula [I], [II] or [III]:
B:X(A)ₙ [I]
A₁—A₂ [II]
B₁—B₂ [III] 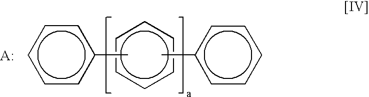
(wherein “X” in the general formula [I] designates a connecting organic group having an “n” valency (“n” is an integer between 2 and 4 both inclusive) excluding condensed polycyclic hydrocarbon compounds; “A” independently designates “n” number of substituted or non-substituted polyphenylene groups in a general formula [IV] (“a” is an integer between 0 and 18 both inclusive); when “X” is benzene group, “A” independently designates the substituted or non-substituted polyphenylene groups in the general formula [IV] (“a” is the integer between 0 and 18 both inclusive) in which “n” is 3 or 4; when “X” is vinylene group, “A” independently designates the substituted or non-substituted polyphenylene groups in the general formula [IV] (“a” is the integer between 0 and 18 both inclusive) in which “n” is 2; A₁ and A₂ in the general formula [II] independently designate substituted or non-substituted polyphenylene groups in the general formula [IV]; and B₁ and B₂ in the general formula [III] independently designate the group represented by the general formula [I]).

8. The organic EL device as defined in claim 7 further comprising an electron-transporting layer, and an interface between the electron-transporting layer and the cathode includes the compound.

9. The organic EL device as defined in claim 8, wherein the compound is mixed with a metal.

10. The organic EL device as defined in claim 8 further comprising an electron-transporting layer, and an interface between the electron-transporting layer and the cathode includes the compound mixed with the metal.

11. The organic EL device as defined in claim 1, wherein the “X” includes the bivalent to tetravalent connecting organic group prepared by removing two to four hydrogen atoms from a non-cyclic hydrocarbon, a monocyclic hydrocarbon, a bridged-cyclic hydrocarbon, a spiro-hydrocarbon or a hydrocarbon having assembled rings.

12. The organic EL device as defined in claim 1, wherein the “X” includes the bivalent to tetravalent connecting organic group prepared by removing two to four hydrogen atoms from cyclohexane, adamantane or benzene.

13. The organic EL device as defined in claim 2, wherein the metal is selected from the group consisting of an alkaline metal including Li, Na, K, Rb, Cs and Fr; an alkaline earth metal including Mg, Ca, Sr, Ba and Ra; and Al, Ga In and Tl.
